(19) United States
(12) Patent Application Publication
(10) Pub. No.: US 2007/0043983 A1
(43) Pub. Date: Feb. 22, 2007

(54) Sample screening method for system soft error rate evaluation

(75) Inventor: Shuen-Chao Kuo, Hsinchu City (TW)

Correspondence Address: BIRCH STEWART KOLASCH & BIRCH, PO BOX 747, FALLS CHURCH, VA, 22040-0747, US

(73) Assignee: Powerchip Semiconductor Corp.

(21) Appl. No.: 11/389,132

(22) Filed: Mar. 27, 2006

(30) Foreign Application Priority Data
Aug. 22, 2005 (TW) 94128584

(51) Int. Cl. G11C 29/00

(52) U.S. Cl. 714/718

(57) ABSTRACT

A sample screening method for system soft error rate evaluation. Memory cells of a memory device are written and read according to a first test condition to locate hard errors. The memory cells of the memory device are read according to a second test condition to locate functional errors. The memory cells of the memory device are read according to a third test condition to locate soft errors.

### BACKGROUND OF THE INVENTION

1. Field of the Invention

The invention relates to data inspection, and more particularly, to a sample screening method for system soft error rate (SSER) evaluation.

2. Description of the Related Art

Dynamic random access memory is composed of metal oxide semiconductor (MOS) transistors and electric capacitors. Binary digital data stored as electric charges may be affected by α particles radiated by the micro radioactive elements of DRAM packing materials, thus changing the data stored in electric capacitors. In opposition to permanent failures, hard errors, generated due to the destruction of isolation layers or the broken circuit of a conducting wire, α particle strokes affecting electric charges of electric capacitors are not regarded as permanent failures but soft errors. A soft error is an error that occurs in a computer memory system that changes an instruction in a program or a data value. Soft errors can be typically remedied by cold booting the computer. A soft error does not damage system hardware, only the data that is being processed.

With respect to high capacity DRAM, smaller element volume results in less capacity of electric charge and more serious problems of soft errors, such that it is critical to improve high density DRAM. Similarly, including DRAM, soft errors are also detected in other types of memory, such as static random access memory (SRAM), capable of charge storage.

Data content is changed due to DRAM hit being hit by α particles in two ways. As shown in FIGS. 1A and 1B, when α particles move along trajectory 140 hitting a memory cell of electric capacity 110, the hits may result in a cell mode error. When the memory cell stores charge “0”, electrons generated by the hit do not affect the stored charge of the memory cell. When the memory cell stores charge “1”, electrons generated by the hit may stream to the memory cell to change “1” to “0”. Additionally, as shown in FIG. 1C, a bit line error of sense amplifier circuit 210 is illustrated. When word line 250 is broken and streams electric potential to word line 230, sense amplifier circuit 210 may detect abnormal signals if word line 230 is hit by α particles to reduce the electric potential, such that electric charge errors comprising “1”→“0” and “0”→“1”are generated.

As described, except for hard errors and soft errors, an error (an access error detected inside the DRAM, for example) may be detected due to other issues during a soft error rate (SER) test, such that more inspections of the DRAM are required during a production manufacturing process, thus decreasing manufacturing efficiency and increasing manufacturing cost. Thus, a sample screening method for system soft error rate (SSER) evaluation is desirable.

### BRIEF SUMMARY OF THE INVENTION

A sample screening method for system soft error rate evaluation is provided. A memory device, comprising a plurality of memory cells, is provided. Each memory cell corresponds to a memory address. Each memory cell is written and read in sequence according to sequences of the memory addresses. It is determined whether a final sequencing memory cell is completely written and read when a writing error is not detected as a current memory cell is written and read according to a first test condition. If not, the next memory cell is written and read. If so, each memory cell of the memory device is read according to the sequences of the memory addresses. It is determined whether the final sequencing memory cell is completely read when a functional error is not detected as a current memory cell is read according to a second test condition. If not, the next memory cell is read. If so, each memory cell of the memory device is read according to the sequences of the memory addresses. It is determined whether the final sequencing memory cell is completely read when a data error is not detected as a current memory cell is read according to a third test condition. If not, the next memory cell is read. If so, it is determined whether the test time of the test process exceeds a preset time, and, if so, the test process is implemented on a next memory device, and, if not, a next memory cell is read.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A and 1B are schematic views of soft errors generated by a DRAM capacitance;

FIG. 1C is a schematic view of soft errors generated by a DRAM induced amplifier;

FIG. 2 is a flowchart of a conventional sample screening method for SER evaluation; and

FIGS. 3A and 3B are flowcharts of an embodiment of a sample screening method for SSER evaluation.

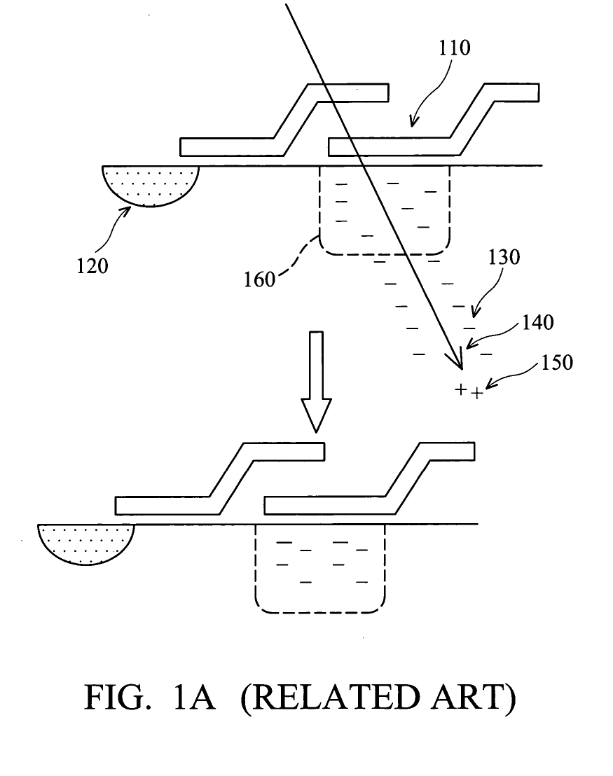

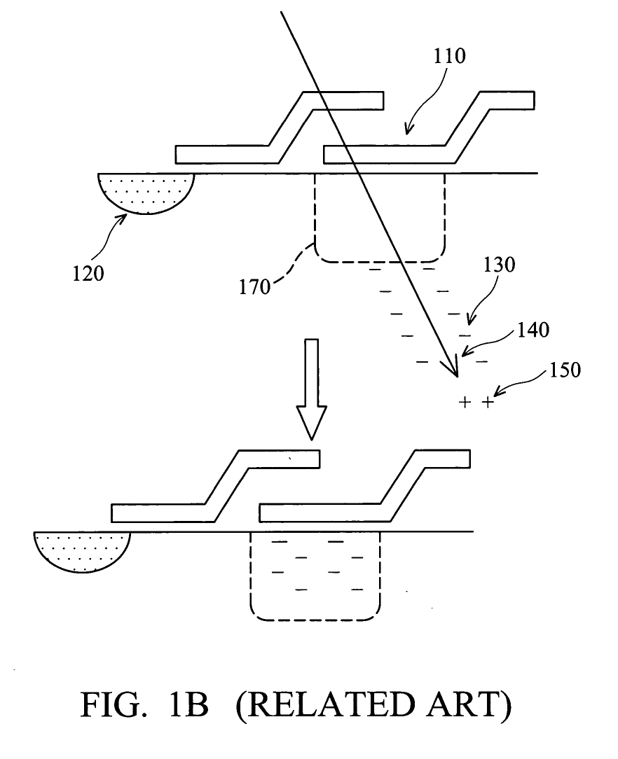

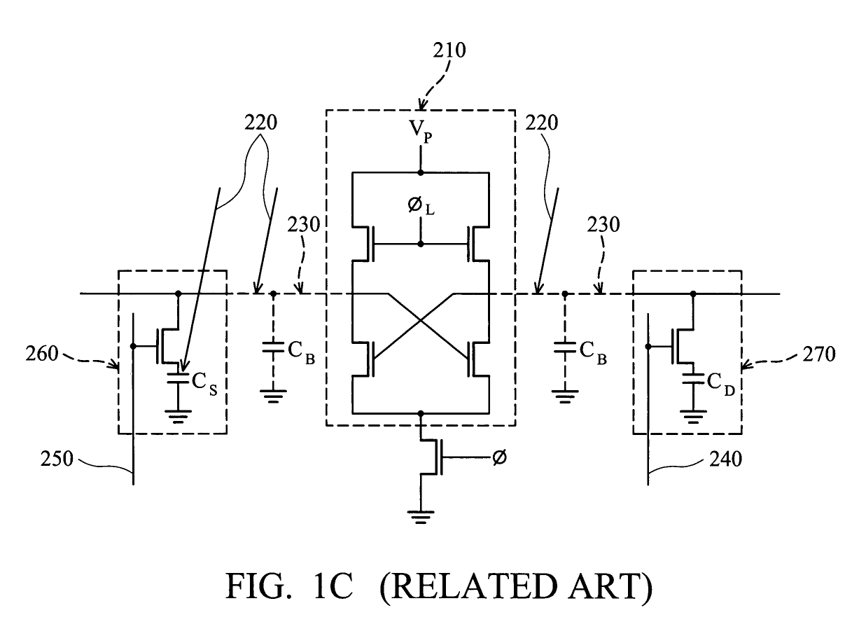

### DETAILED DESCRIPTION OF THE INVENTION

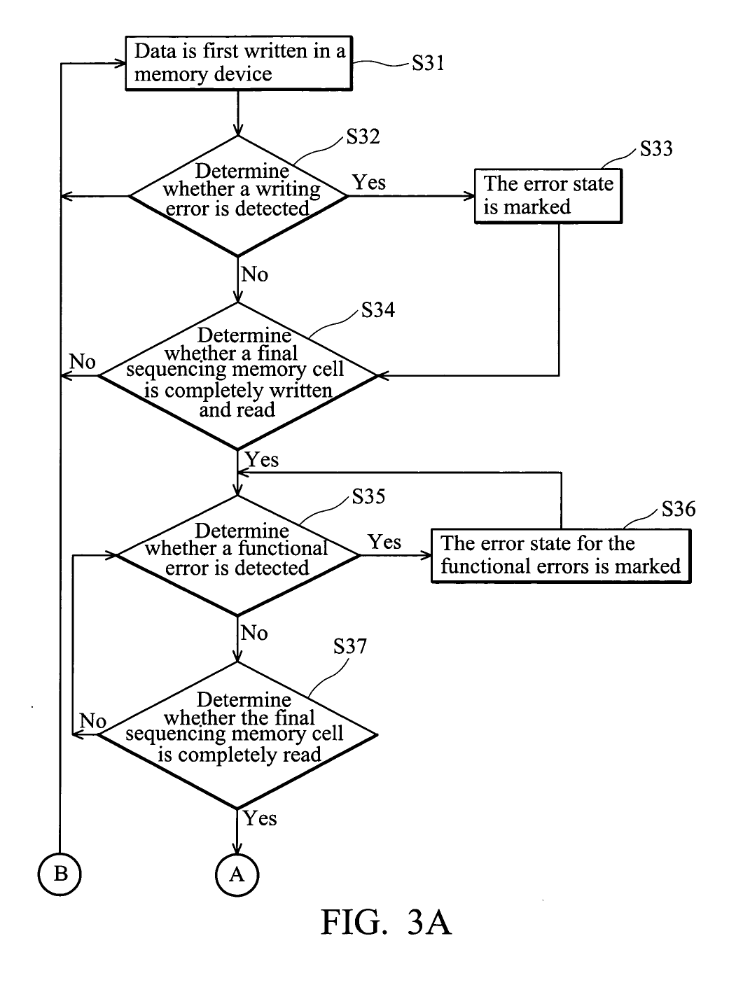

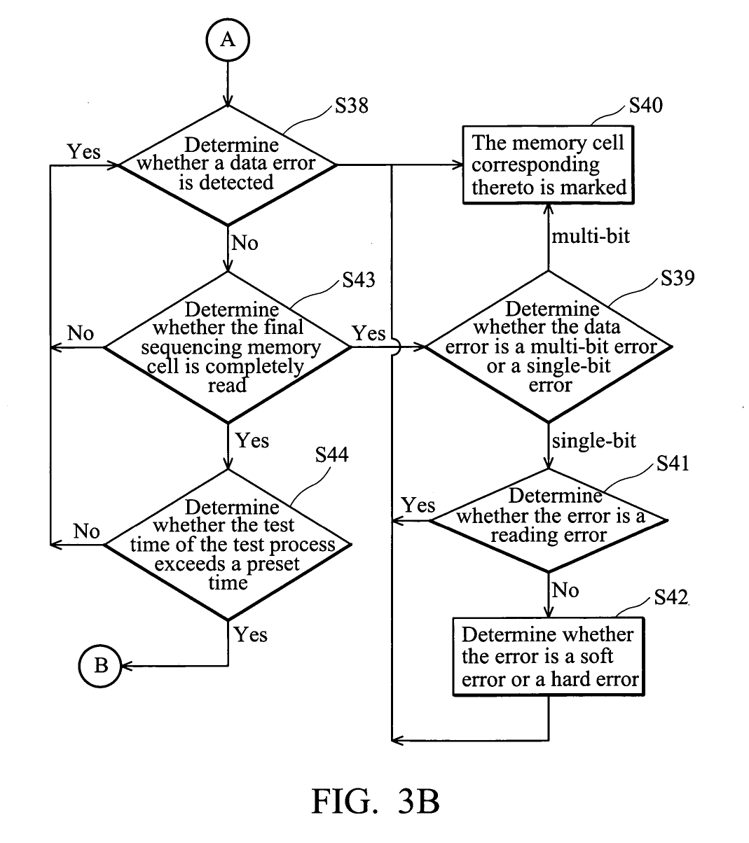

Several exemplary embodiments of the invention are described with reference to FIGS. 3a and 3B, which generally relate to a sample screening method for SSER evaluation. It is to be understood that the following disclosure provides many different embodiments as examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

The invention discloses a sample screening method for system soft error rate (SSER) evaluation.

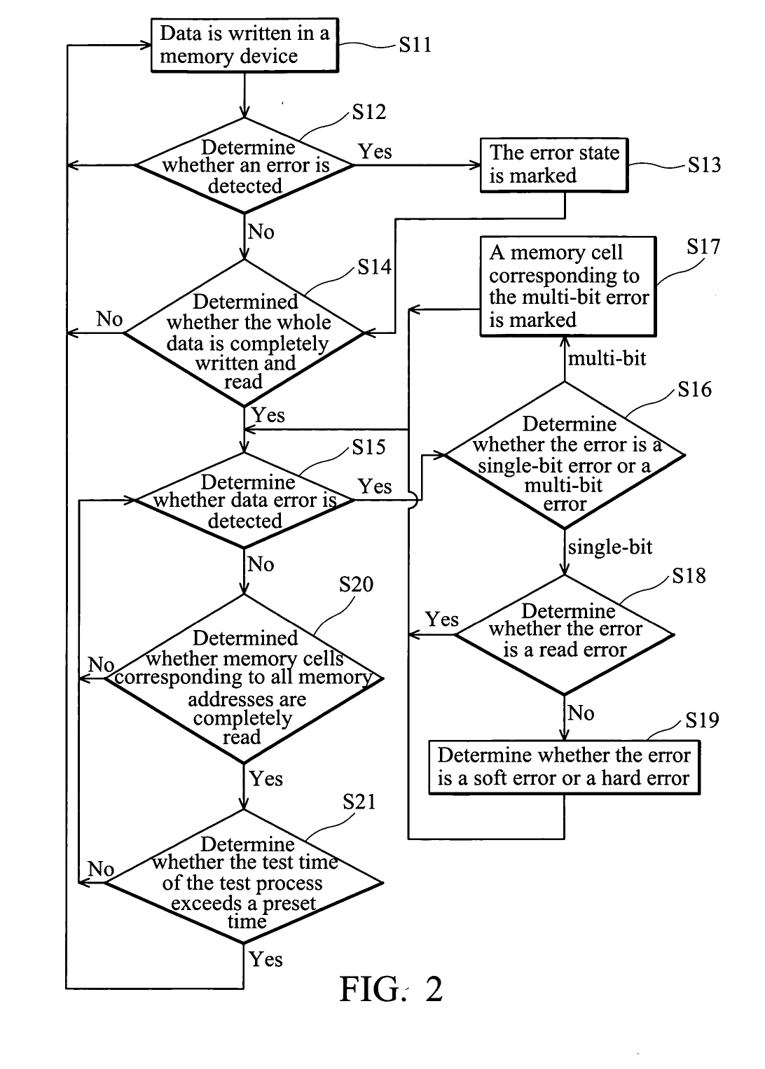

FIG. 2 is a flowchart of a conventional sample screening method for SER evaluation.

Data is first written in a memory device (step S11). In this embodiment, data indicates electric charge “0” or “1” stored in DRAM, a memory cell. Next, data stored in the memory cell is read and it is determined whether an error is detected (step S12). When data “0.1. 0.1. 0.1...” is written in and data “0.1.1.1.0.1...” is read out, indicating an error is detected, the error state is marked (step S13), and the process proceeds to step S14.

If no error is detected, it is determined whether all the data is completely written and read (step S14). The relationship between a test system and a test board is represented by a matrix, in which data of each integrated circuit (IC) row of the test board corresponds to a memory address of the test system. Data is written and read according to sequences of the memory addresses. Thus, the step determines whether memory cells corresponding to each memory address are completely written and read. If so, the process proceeds to step S15. If not, a memory cell corresponding to a next memory address is written and read (step S11). Steps S11˜S14 inspect whether all the data can be successfully written and read from memory cells, mark error states, and further test normal memory cells.

Next, normal memory cells are read according to sequences of the memory address and it is determined whether a data error is detected (step S15). If so, the process proceeds to step S16, and, if not, to step S20. It is determined whether the error is a single-bit error or a multi-bit error (step S16). If the error is a multi-bit error, a memory cell corresponding to the multi-bit error is marked (step S17), the write and read operations are further implemented on the current memory cell, and the process proceeds to step S15. If the error is a single-bit error, a memory cell corresponding thereto is implemented on a marginal test and read to determine whether the error is a read error (step S18). If data can be normally read, the error is a temporary error, detected due to abnormalities of the test system itself, or a read error, detected due to external noise relating the memory cell. The write and read operations described are further implemented on the current memory cell and the process proceeds to step S15. If data cannot be normally read, it is determined whether the error is a soft error or a hard error (step S19). Data is written in a memory cell of DRAM and represented as “0” or “1”. As described, when α particles directly hit electric capacitors, the data may change from “1” to “0”. Data “1”, for example, stored in an electric capacity charges 2 voltages (2V) and, when α particles hit the electric capacity, the charge leaks to change the data to “0”. Thus, writing data “0” and reading data “1” indicates a read error is detected. When the determination in step S19 is complete, the write and read operations executed described are further implemented on the current memory cell and the process proceeds to step S15.

Next, if an error is not detected when a current memory cell is read, it is determined whether memory cells corresponding to all memory addresses are completely read (step S20). If so, the process proceeds to step S21, and, if not, to step S15 to read a memory cell corresponding to the next memory address. If memory cells corresponding to all memory addresses are completely read, it is determined whether the test time of the test process exceeds a preset time (1000 hours, for example) (step S21). If so, the process proceeds to step S11 to repeat steps S11˜S21 for another memory device, and, if not, to step S15 to read a memory cell corresponding to the next memory address.

As described, except for hard and soft errors, when a test for a soft error is implemented, errors relating to DRAM may be detected due to other errors, such as read errors inside the DRAM, such that more inspections are required, reducing manufacturing efficiency or increasing cost. Thus, the invention joins another test flow to the original test flow to catch other errors before soft errors, described in the following.

FIGS. 3A and 3B are flowcharts of an embodiment of a sample screening method for SSER evaluation.

Steps S31˜S34 is equivalent to steps S11˜S14. Data is written in a memory device comprising a plurality of memory cells (step S31). As described, data indicates electric charge “0” or “1” stored in DRAM. Each memory cell is read in sequence according to sequences of the memory addresses and it is determined whether a writing error is detected according to a first test condition (step S32). If so, the process proceeds to step S33, and, if not, to step S34. When data “0.1. 0.1. 0.1...” is written in and data “0.1.1.1.0.1... ” is read out, indicating an error is detected, the error state is marked (step S33).

Next, it is determined whether a final sequencing memory cell is completely written and read (step S34). If so, the process proceeds to step S35. If not, a memory cell corresponding to a next memory address is written and read. Steps S31˜S34 inspect whether other errors (such as system errors or hard errors) relating to memory cells are detected except for soft errors. In the described test process, test conditions are more critical to catching abnormal memory cells to increase efficiency of the posterior test processes. Next, abnormal memory cells are marked and the test process is further implemented on normal memory cells.

Next, memory cells are read and it is determined whether a functional error is detected according to a second test condition (step S35). Abnormities inside a memory device may result in functional errors. Data, for example, stored in a memory device leaks as time passes. Additionally, the test system complications or external noise may also result in functional errors. If a functional error is detected, the error state for the functional errors is marked. (step S36) and the process proceeds to step S35. If not, it is determined whether the final sequencing memory cell is completely read (step S37), and, if not, the process proceeds to step S35.

When memory cells corresponding to each memory address are completely read, it is determined whether a data error is detected according to a third test condition (step S38). If so, it is then determined whether the data error is a multi-bit error or a single-bit error (step S39). If the data error is a multi-bit error, the corresponding memory cell is marked (step S40). If the data error is a single-bit error, a marginal test is implemented on the tested memory cell to determine whether the error is a reading error (step S41). If data can be normally read, the error is a temporary error, detected due to abnormalities of the test system itself, or a read error, detected due to external noises relating the memory cell. The write and read operations described are further implemented on the current memory cell and the process proceeds to step S38. If data cannot be normally read, it is determined whether the error is a soft error or a hard error (step S42), the write and read operations are further executed implemented on the current memory cell, and the process proceeds to step S38.

Next, if no data error is detected according to the third test condition, it is determined whether the final sequencing memory cell is completely read (step S43). If not, the process proceeds to step S38. If so, it is determined whether the test time of the test process exceeds a preset time (1000 hours, for example) (step S44). If so, the process proceeds to step S31 to repeat steps S31˜S44 to another memory device, and, if not, to step S38 to read a memory cell corresponding to the next memory address.

A sample screening method of the invention can locate other types of errors (such as system errors or hard errors) before soft errors are caught, thus increasing process efficiency and reducing manufacturing cost.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A sample screening method for system soft error rate evaluation, comprising:
(a) providing a memory device, comprising a plurality of memory cells, each corresponding to a memory address;
(b) writing and reading each memory cell in sequence according to sequences of the memory addresses;
(c) determining whether a final sequencing memory cell is completely written and read when a writing error is not detected as a current memory cell is written and read according to a first test condition;
(d) if not, writing and reading the next memory cell;
(e) if so, reading each memory cell of the memory device according to the sequences of the memory addresses;
(f) determining whether the final sequencing memory cell is completely read when a functional error is not detected as a current memory cell is read according to a second test condition;
(g) if not, reading the next memory cell;
(h) if so, reading each memory cell of the memory device according to the sequences of the memory addresses;
(i) determining whether the final sequencing memory cell is completely read when a data error is not detected as a current memory cell is read according to a third test condition;
(j) if not, reading the next memory cell;
(k) if so, determining whether the test time of the test process exceeds a preset time;
(l) if so, implementing the test processes on a next memory device; and
(m) if not, reading a next memory cell.

2. The sample screening method as claimed in claim 1, wherein step (c) further comprises (c1) recording the writing error state when the writing error is detected as a current memory cell is written and read according to the first test condition.

3. The sample screening method as claimed in claim 1, wherein step (f) further comprises (f1) recording the functional error state when the functional error is detected as a current memory cell is read according to the second test condition.

4. The sample screening method as claimed in claim 1, wherein step (i) further comprises:
(i1) determining whether the data error is a multi-bit error or a single-bit error when a data error is detected as a current memory cell is read according to the third test condition;
(i2) if the data error is a multi-bit error, marking the current memory cell; and
(i3) if the data error is a single-bit error, implementing a marginal test on and reading the tested memory cell; and determining the data error is a soft error or a hard error when the data error is not a reading error.

5. A storage medium for storing a computer program providing a sample screening method for system soft error rate evaluation, comprising using a computer to perform the steps of:
(a) providing a memory device, comprising a plurality of memory cells, each corresponding to a memory address;
(b) writing and reading each memory cell in sequence according to sequences of the memory addresses;
(c) determining whether a final sequencing memory cell is completely written and read when a writing error is not detected as a current memory cell is written and read according to a first test condition;
(d) if not, writing and reading the next memory cell;
(e) if so, reading each memory cell of the memory device according to the sequences of the memory addresses;
(f) determining whether the final sequencing memory cell is completely read when a functional error is not detected as a current memory cell is read according to a second test condition;
(g) if not, reading the next memory cell;
(h) if so, reading each memory cell of the memory device according to the sequences of the memory addresses;
(i) determining whether the final sequencing memory cell is completely read when a data error is not detected as a current memory cell is read according to a third test condition;
(j) if not, reading the next memory cell;
(k) if so, determining whether the test time of the test process exceeds a preset time;
(l) if so, implementing the test processes on a next memory device; and
(m) if not, reading a next memory cell.

6. The storage medium as claimed in claim 5, wherein step (c) further comprises (c1) recording a writing error state when a writing error is detected as a current memory cell is written and read according to the first test condition.

7. The storage medium as claimed in claim 5, wherein step (f) further comprises (f1) recording a functional error state when a functional error is detected as a current memory cell is read according to the second test condition.

8. The storage medium as claimed in claim 5, wherein step (i) further comprises:
(i1) determining whether the data error is a multi-bit error or a single-bit error when a data error is detected as a current memory cell is read according to the third test condition;
(i2) if the data error is a multi-bit error, marking the current memory cell; and
(i3) if the data error is a single-bit error, implementing a marginal test on and reading the tested memory cell; and determining the data error is a soft error or a hard error when the data error is not a reading error.
